(19) United States
(12) Patent Application Publication
(10) Pub. No.: US 2021/0263355 A1
(43) Pub. Date: Aug. 26, 2021

(54) DISPLAY DEVICE AND METHOD OF FABRICATING THE SAME

(71) Applicant: SAMSUNG DISPLAY CO., LTD., Yongin-si (KR)

(72) Inventor: Do Yeong PARK, Hwaseong-si (KR)

(21) Appl. No.: 17/035,975

(22) Filed: Sep. 29, 2020

(30) Foreign Application Priority Data
Feb. 21, 2020 (KR) 10-2020-0021632

(51) Int. Cl. G02F 1/1368; H01L 27/12; G02F 1/1362

(52) U.S. Cl. CPC G02F 1/1368; H01L 27/1288; G02F 2001/136222; G02F 1/136227; G02F 1/13624; G02F 1/136286

(57) ABSTRACT

A display device includes a substrate and a first metal layer disposed on the substrate. The first metal layer including first metal parts. Organic film patterns are disposed on the substrate and are positioned adjacent to lateral edges of the first metal parts of the first metal layer. A gate insulating pattern is disposed on the first metal parts of the first metal layer and the organic film patterns. A semiconductor pattern is disposed on the gate insulating pattern. Lateral side surfaces of the gate insulating pattern protrude outward from the lateral edges of each first metal part of the first metal layer that the gate insulating pattern is disposed thereon. The gate insulating pattern at least partially overlaps each organic film pattern that the gate insulating pattern is disposed thereon.

### CROSS REFERENCE TO RELATED APPLICATION(S)

This application claims priority under 35 U.S.C. § 119 to Korean Patent Application No. 10-2020-0021632, filed on Feb. 21, 2020, in the Korean Intellectual Property Office, the disclosure of which is incorporated herein by reference in its entirety herein.

### 1. TECHNICAL FIELD

The present inventive concepts relate to a display device and a method for fabricating the same.

### 2. DISCUSSION OF RELATED ART

As multimedia technology has progressed, display devices have become increasingly important. Various types of display devices have been developed, such as liquid-crystal display (LCD) devices and organic light-emitting display (OLED) devices.

An LCD device is one of the most commonly used flat panel display devices. An LCD device includes two substrates in which field generating electrodes such as pixel electrodes and a common electrode are formed, and a liquid-crystal layer is disposed therebetween. An LCD device applies a voltage to field generating electrodes to generate an electric field across a liquid-crystal layer. The liquid-crystal molecules in the liquid-crystal layer are aligned by the electric field so as to control the polarization of incident light for displaying an image.

An LCD device may be an active matrix LCD device which uses thin-film transistors. Thin-film transistors are connected to pixel electrodes, and pixels are driven by the voltage held by capacitor capacitances of the thin-film transistors. Thin-film transistors used in active matrix LCD devices should have a good durability to provide a long lifespan and excellent electrical reliability, in addition to the basic characteristics of thin-film transistors such as high carrier mobility and low leakage current. Therefore, it is desirable to provide thin-film transistors having an improved durability and electrical reliability.

### SUMMARY

Aspects of the present inventive concepts provide a display device that may prevent a short-circuit between a first metal layer and a second metal layer, and a method of fabricating the same. Aspects of the present inventive concepts also provide a display device that may improve an aperture ratio by reducing the area of a contact hole, and a method of fabricating the same.

According to an exemplary embodiment of the present inventive concepts, a display device includes the organic film patterns disposed between the first metal layer and the second metal layer, thereby preventing the first metal layer and the second metal layer from being in direct contact with each other to create a short-circuit. Further, by filling the pores between the first metal layer and the second metal layer with the organic film patterns, corrosion of the first metal layer may be prevented.

It should be noted that effects of the present inventive concepts are not limited to those described above and other effects of the present inventive concepts will be apparent to those skilled in the art from the following descriptions.

According to an exemplary embodiment of the present inventive concepts, a display device includes a substrate and a first metal layer disposed on the substrate. The first metal layer including first metal parts. Organic film patterns are disposed on the substrate and are positioned adjacent to lateral edges of the first metal parts of the first metal layer. A gate insulating pattern is disposed on the first metal parts of the first metal layer and the organic film patterns. A semiconductor pattern is disposed on the gate insulating pattern. Lateral side surfaces of the gate insulating pattern protrude outward from the lateral edges of each first metal part of the first metal layer that the gate insulating pattern is disposed thereon. The gate insulating pattern at least partially overlaps each organic film pattern that the gate insulating pattern is disposed thereon.

In an exemplary embodiment, the organic film patterns are in contact with the side surfaces of the first metal layer.

In an exemplary embodiment, outer side surfaces of the organic film patterns are aligned with or protrude from the side surfaces of the gate insulating pattern.

In an exemplary embodiment, the first metal layer comprises a first side surface located on a side and a second side surface located on an opposite side, wherein one of the organic film patterns is in contact with the first side surface of the first metal layer, and wherein another one of the organic film patterns is in contact with the second side surface of the first metal layer.

In an exemplary embodiment, the organic film patterns are in contact with one side of the first metal layer and in contact with a lower side of the gate insulating pattern.

In an exemplary embodiment, the display device further comprises a second metal layer disposed on the semiconductor pattern, a portion of the second metal layer is positioned at a same level as the first metal layer and is electrically insulated from the first metal layer by the organic film patterns.

In an exemplary embodiment, the semiconductor pattern and the gate insulating pattern comprises a contact hole exposing the first metal layer, and wherein the second metal layer is connected to the first metal layer through the contact hole.

In an exemplary embodiment, the first metal layer comprises a gate electrode and a storage line, and wherein the second metal layer comprises a source electrode, a drain electrode, and a voltage-dividing reference line.

According to an exemplary embodiment of the present inventive concepts, a display device includes a substrate. A first metal layer is disposed on the substrate. The first metal layer includes first metal parts. Organic film patterns are disposed on the substrate and are positioned adjacent to lateral edges of the first metal parts of the first metal layer. A gate insulating pattern is disposed on the first metal parts of the first metal layer and the organic film patterns. A semiconductor pattern is disposed on the gate insulating pattern. Lateral side surfaces of the gate insulating pattern protrude outward from the lateral edges of each first metal part of the first metal layer that the gate insulating pattern is disposed thereon. The organic film patterns directly contact lateral edges of the gate insulating pattern.

In an exemplary embodiment, the organic film patterns are in contact with side surfaces of the semiconductor pattern.

In an exemplary embodiment, outer side surfaces of the organic film patterns protrude from the side surfaces of the gate insulating pattern.

In an exemplary embodiment, the first metal layer comprises a first side surface located on a side and a second side surface located on an opposite side, wherein one of the organic film patterns is in contact with the first side surface of the first metal layer, and wherein another one of the organic film patterns is in contact with the second side surface of the first metal layer.

In an exemplary embodiment, the organic film patterns are in contact with one side of the first metal layer and in contact with a lower side of the gate insulating pattern.

In an exemplary embodiment, the display device further comprises a second metal layer disposed on the semiconductor pattern, a portion of the second metal layer is positioned at a same level as the first metal layer and is electrically insulated from the first metal layer by the organic film patterns.

In an exemplary embodiment, the second metal layer is disposed on outer sides of and in contact with the organic film patterns.

In an exemplary embodiment, the organic film patterns are disposed between the first metal layer and the second metal layer, one side of the organic film patterns is in contact with the side surfaces of the first metal layer and the other side of the organic film patterns is in contact with side surfaces of the second metal layer.

According to an exemplary embodiment of the present inventive concepts, a method of fabricating a display device includes stacking a first metal material layer, a gate insulating material layer and a semiconductor material layer on a substrate. A first metal layer, a gate insulating pattern and a semiconductor pattern is formed by etching the first metal material layer, the gate insulating material layer and the semiconductor material layer. Organic film patterns are formed that are positioned adjacent to lateral edges of the first metal layer by coating an organic material on the substrate. A second metal layer is formed by stacking and patterning a second metal material layer on the semiconductor pattern.

In an exemplary embodiment, the forming the first metal layer, the gate insulating pattern and the semiconductor pattern comprises forming a photoresist pattern on the semiconductor material layer, forming the first metal layer by wet etching the first metal material layer, forming the gate insulating pattern and the semiconductor pattern by dry etching the gate insulating material layer and the semiconductor material layer, and removing the photoresist pattern.

In an exemplary embodiment, the organic material is a photosensitive organic material, and wherein the organic film patterns are formed by exposing and developing the photosensitive organic material using the gate insulating pattern as a mask.

In an exemplary embodiment, the organic material is a non-photosensitive organic material, and wherein the organic film patterns are formed by dry etching the non-photosensitive organic material using the photoresist pattern as a mask.

### BRIEF DESCRIPTION OF THE DRAWINGS

The above and other aspects and features of the present inventive concepts will become more apparent by describing in detail exemplary embodiments thereof with reference to the attached drawings, in which:

FIG. 1 is a plan view showing a display device according to an exemplary embodiment of the present inventive concepts.

FIG. 2 is a plan view showing a pixel of FIG. 1 according to an exemplary embodiment of the present inventive concepts.

FIG. 3 is a cross-sectional view taken along line I-I′ of FIG. 2 according to an exemplary embodiment of the present inventive concepts.

FIG. 4 is a plan view showing a pixel of FIG. 1 according to an exemplary embodiment of the present inventive concepts.

FIG. 5 is a cross-sectional view showing a pixel of a display device according to an exemplary embodiment of the present inventive concepts.

FIGS. 6 to 15 are cross-sectional views showing steps of a method of fabricating a display device according to exemplary embodiments of the present inventive concepts.

FIGS. 16 and 17 are cross-sectional views showing processing steps of a method of fabricating a display device according to another exemplary embodiment of the present inventive concepts.

FIG. 18 is a cross-sectional view of a pixel of a display device according to another exemplary embodiment of the present inventive concepts.

FIGS. 19 to 23 are cross-sectional views showing steps of a method of fabricating a display device according to other exemplary embodiments of the present inventive concepts.

### DETAILED DESCRIPTION OF EXEMPLARY EMBODIMENTS

The present inventive concepts will now be described more fully hereinafter with reference to the accompanying drawings, in which exemplary embodiments of the present inventive concepts are shown. The present inventive concepts may, however, be embodied in different forms and should not be construed as limited to the exemplary embodiments set forth herein.

It will also be understood that when a layer is referred to as being “on” another layer or substrate, it can be directly on the other layer or substrate, or intervening layers may also be present. The same reference numbers indicate the same components throughout the specification. However, when a layer is referred to as being “directly on” another layer or substrate, no intervening layers may be present.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present inventive concepts. Similarly, the second element could also be termed the first element.

In the specification, the meaning of being located on the same layer includes the meaning that the layers located immediately below each component are the same as each other, or that each component is located on the same level. Throughout the specification, when an element is referred to as being “connected” to another element, the element may be “directly connected” to another element, or “electrically connected” to another element with one or more intervening elements interposed therebetween.

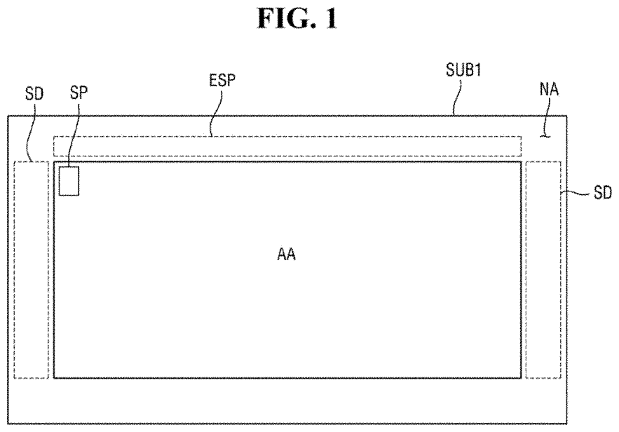

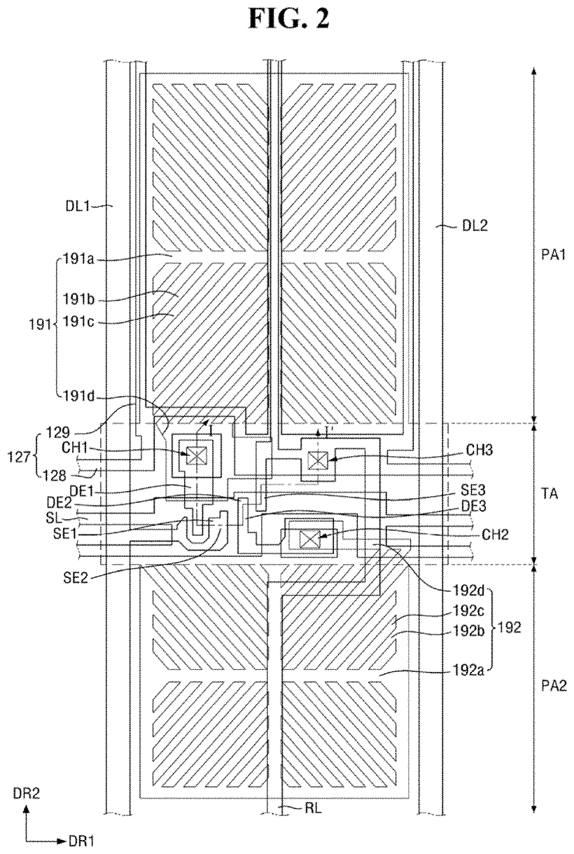

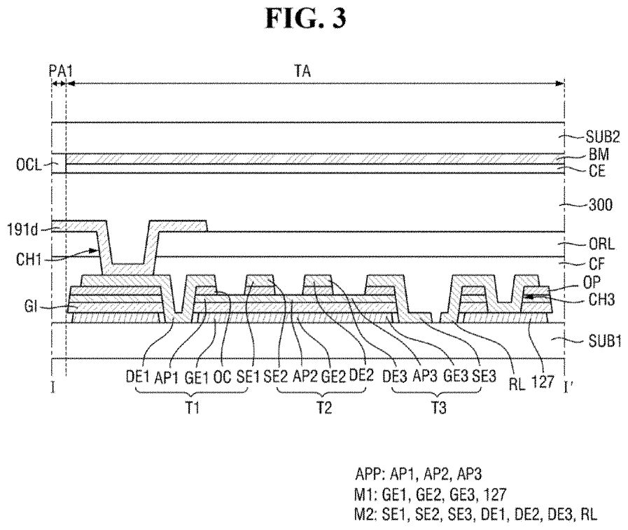

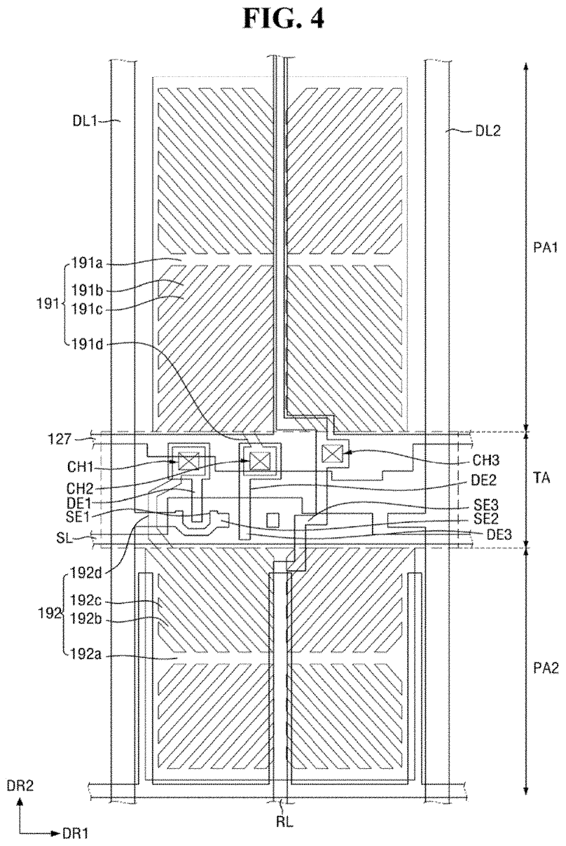

FIG. 1 is a plan view showing a display device according to an exemplary embodiment of the present inventive concepts. FIG. 2 is a plan view showing a pixel of FIG. 1 according to an exemplary embodiment of the present inventive concepts. FIG. 3 is a cross-sectional view taken along line I-I′ of FIG. 2 according to an exemplary embodiment of the present inventive concepts. FIG. 4 is a plan view showing a pixel of FIG. 1 according to another exemplary embodiment of the present inventive concepts.

Referring to FIG. 1, a display device according to an exemplary embodiment of the present inventive concepts may include a display area AA and a non-display area NA on a first substrate SUB1. As shown in the exemplary embodiment of FIG. 1, the non-display area NA may surround the display area AA. For example, the non-display area NA in the exemplary embodiment of FIG. 1 surrounds all four sides of the display area AA. However, exemplary embodiment of the present inventive concepts are not limited thereto. The non-display area NA may include gate drivers SD disposed on the left and right sides of the first substrate SUB1, respectively, and an electrostatic discharge part ESP disposed on the upper side of the substrate SUB.

The display area AA may include a plurality of sub-pixels SP. For example, in an exemplary embodiment, a red sub-pixel, a green sub-pixel and a blue sub-pixel may form a single unit pixel, or a red sub-pixel, a green sub-pixel, a blue sub-pixel and a white sub-pixel may form a single unit pixel. However, exemplary embodiments of the present inventive concepts are not limited thereto and the sub-pixels may be arranged to have various different colors in other exemplary embodiments. The sub-pixels SP may all have the same area or different sub-pixels may have different areas.

The gate drivers SD apply gate driving signals to the display area AA. Although the exemplary embodiment of FIG. 1 shows two gate drivers SD disposed on both sides (e.g., left and right sides) of the display area AA, exemplary embodiments of the present inventive concepts are not limited thereto and the gate drivers SD may be variously arranged and have different numbers in other exemplary embodiments. For example, in an exemplary embodiment, only one gate driver may be disposed on one side of the display area AA. The electrostatic discharge part ESP may be disposed on a side of the display area AA. For example, as shown in the exemplary embodiment of FIG. 1, the electrostatic discharge part ESP may be disposed on the upper side to prevent static electricity from being introduced into signal lines. However, exemplary embodiments of the present inventive concepts are not limited thereto, and the display device may include one or more electrostatic discharge part ESP that are variously arranged in other exemplary embodiments of the present inventive concepts. For example, in an exemplary embodiment, the electrostatic discharge part ESP may be disposed on each of the upper and lower sides of the display area AA.

Hereinafter, planar and cross-sectional structures of a sub-pixel SP of a display device will be described with reference to the exemplary embodiments of FIGS. 2 and 3.

Referring to the exemplary embodiments of FIGS. 2 and 3, a unit pixel may include a first sub-pixel area PA1, a second sub-pixel area PA2, and a switching element area TA that are arranged in a second direction DR2. The first sub-pixel area PA1 may be defined as the area where a first stem electrode 191a and first branch electrodes 191b of a first sub-pixel electrode 191 are disposed. The second sub-pixel area PA2 may be defined as the area where a second stem electrode 192a and second branch electrodes 192b of a second sub-pixel electrode 192 are disposed. The switching element area TA may be defined as the area where a plurality of switching elements, such as a first switching element T1, a second switching element T2, a third switching element T3, etc. are disposed. The switching element area TA may be located between the first sub-pixel area PA1 and the second sub-pixel area PA2 in the second direction DR2.

In an exemplary embodiment, the first substrate SUB1 may include an insulating material such as at least one material selected from glass, quartz and a polymer resin. For example, the polymer material may include polyethersulphone (PES), polyacrylate (PA), polyacrylate (PAR), polyetherimide (PET), polyethylene naphthalate (PEN), polyethylene terephthalate (PET), polyphenylene sulfide (PPS), polyallylate, polyimide (PI), polycarbonate (PC), cellulose triacetate (CAT) and cellulose acetate propionate (CAP) or a combination thereof. The first substrate SUB1 may include a metal material.

As shown in the exemplary embodiment of FIG. 3, a first metal layer M1 may be disposed on the first substrate SUB1. The first metal layer M1 may include a scan line SL, a first gate electrode GE1, a second gate electrode GE2, and a third gate electrode GE3. The scan line SL, the first gate electrode GE1, the second gate electrode GE2 and the third gate electrode GE3 may be disposed on the same layer and may include the same material. The scan line SL may extend substantially in the first direction DR1. The first gate electrode GE1, the second gate electrode GE2, and the third gate electrode GE3 may be electrically connected to the scan line SL. The first gate electrode GE1, the second gate electrode GE2, and the third gate electrode GE3 may be connected to each other. For example, as shown in the exemplary embodiment of FIG. 3, the first gate electrode GE1, the second gate electrode GE2, and the third gate electrode GE3 may be formed of a unitary electrode. The scan line SL may be spaced apart from the first gate electrode GE1, the second gate electrode GE2, and the third gate electrode GE3. However, exemplary embodiments of the present inventive concepts are not limited thereto and in other exemplary embodiments, the first gate electrode GE1, the second gate electrode GE2, and the third gate electrode GE3 may be variously arranged, such as in discrete, spaced apart electrodes.

The first metal layer M1 may be formed of a single layer or multiple layers. In an exemplary embodiment in which the first metal layer M1 is formed of a single layer, the first metal layer M1 may include one compound selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Cs), titanium (Ti), tantalum (Ta), tungsten (W) and copper (Cu) or an alloy thereof. In addition, when the first metal layer M1 is formed of multiple layers, it may be formed of the above-listed materials. For example, in an exemplary embodiment, the first metal layer M1 may include two layers of molybdenum/aluminum-neodymium, molybdenum/aluminum, or copper/titanium.

A gate insulating pattern GI may be disposed on the scan line SL, the first gate electrode GE1, the second gate electrode GE2, the third gate electrode GE3 and a storage line 127, to insulate them from one another. In an exemplary embodiment, the gate insulating pattern GI may include inorganic insulating materials such as silicon compounds and metal oxides. For example, the gate insulating pattern G may include silicon oxide, silicon nitride, silicon oxynitride, aluminum oxide, tantalum oxide, hafnium oxide, zirconium oxide, titanium oxide, or a combination thereof. The gate insulating pattern GI may be formed of a single layer or multiple layers of different materials.

The gate insulating pattern GI may be disposed on the first metal layer M1. For example, the gate insulating pattern GI may be disposed on the scan line SL, the first gate electrode GE1, the second gate electrode GE2, the third gate electrode GE3 and the storage line 127. The first metal layer M1 is disposed under the gate insulating pattern GI. For example, the scan line SL, the first gate electrode GE1, the second gate electrode GE2, the third gate electrode GE3 and the storage line 127 may be formed in an undercut shape underneath the gate insulating pattern GL. A lower surface of the gate insulating pattern GI may directly contact upper surfaces of the scan line SL, the first gate electrode GE1, the second gate electrode GE2, the third gate electrode GE3 and the storage line 127.

A semiconductor pattern APP may be disposed on the gate insulating pattern GI. The semiconductor pattern APP may include a first semiconductor region AP1, a second semiconductor region AP2, and a third semiconductor region AP3.

The first semiconductor region AP1 may overlap the first gate electrode GE1 (e.g., in a thickness direction of the first substrate SUB1). The second semiconductor region AP2 may overlap the second gate electrode GE2 (e.g., in a thickness direction of the first substrate SUB1). The third semiconductor region AP3 may overlap the third gate electrode GE3 (e.g., in a thickness direction of the first substrate SUB1). For example, in the exemplary embodiment shown in FIG. 3, the semiconductor pattern APP overlapping the first to third gate electrodes GE1, GE2 and GE3 may be the first semiconductor region AP1, the second semiconductor region AP2, and the third semiconductor region AP3. In each of the first semiconductor region AP1, the second semiconductor region AP2 and the third semiconductor region AP3, a channel may be formed as the conductivity is reversed between the source electrode and the drain electrode (or a channel region) when an electric field is applied by the gate electrode overlapping it. In an exemplary embodiment, the first semiconductor region AP1, the second semiconductor region AP2 and the third semiconductor region AP3 may be formed in a single pattern. However, exemplary embodiments of the present inventive concepts are not limited thereto.

According to an exemplary embodiment of the present inventive concepts, the semiconductor pattern APP may include a silicon-based semiconductor material such as at least one material selected from amorphous silicon, polycrystalline silicon and monocrystalline silicon. In another exemplary embodiment, the semiconductor pattern APP may include at least one compound selected from monocrystalline silicon, low-temperature polycrystalline silicon, amorphous silicon, etc. In addition, the semiconductor pattern APP may include an oxide semiconductor as well. For example, the semiconductor pattern APP may include a binary compound (ABx), a ternary compound (ABxCy) and a quaternary compound (ABxCyDz) containing indium (In), zinc (Zn), gallium (Ga), tin (Sn), titanium (Ti), aluminum (Al), hafnium (Hf), zirconium (Zr), magnesium (Mg), etc. The semiconductor pattern APP may also include ITZO (oxide containing indium, tin, and titanium) or IGZO (oxide including indium, gallium, and tin).

An ohmic pattern OP may be disposed on the semiconductor pattern APP. The ohmic pattern OP may include ohmic contact layers OC. The ohmic contact layers OC may be disposed between source and drain electrodes to be described below and portions the semiconductor pattern APP, to lower the Schottky barrier between metal and silicon, e.g., the work function to thereby reduce a contact resistance. According to an exemplary embodiment, the ohmic pattern OP may be disposed on the semiconductor pattern APP, and the portions of the ohmic pattern OP overlapping the source and drain electrodes and the first to third semiconductor regions AP1, AP2 and AP3 may be the ohmic contact layers OC. In the following description, the other regions of the ohmic pattern OP aside from the ohmic contact layers OC are referred to as the ohmic pattern OP.

The ohmic pattern OP may include amorphous silicon doped with n-type impurities at a high concentration. The ohmic contact layers OC may be disposed on the first semiconductor region AP1, the second semiconductor region AP2, and the third semiconductor region AP3. For example, as shown in the exemplary embodiment of FIG. 3, a lower surface of the ohmic contact layers OC directly contact upper surfaces of the first semiconductor region AP1, the second semiconductor region AP2, and the third semiconductor region AP3. Adjacent ohmic contact layers OC disposed on the first semiconductor region AP1, the second semiconductor region AP2 and the third semiconductor region AP3 may be spaced apart from each other. The region of the semiconductor pattern APP between the ohmic contact layers OC may function as channels.

According to this exemplary embodiment, the gate insulating pattern GI, the semiconductor pattern APP and the ohmic pattern OP may be disposed on the first metal layer M1. In an exemplary embodiment of a method of fabricating a display device to be described later, the first metal layer M1, the gate insulating pattern GI, the semiconductor pattern APP and the ohmic pattern OP may be simultaneously patterned with a single mask, so that the gate insulating pattern GI, the semiconductor pattern APP and the ohmic pattern OP may be disposed on the first metal layer M1.

As shown in the exemplary embodiment of FIG. 3, a second metal layer M2 may be disposed on the first substrate SUB1 and the ohmic pattern OP. The second metal layer M2 may include a first data line DL1, a second data line DL2, a first source electrode SE1, a first drain electrode DE1, a second source electrode SE2, a second drain electrode DE2, a third source electrode SE3, a third drain electrode DE3 and a voltage-dividing reference line RL. In an exemplary embodiment, the first data line DL1, the second data line DL2, the first source electrode SE1, the first drain electrode DE1, the second source electrode SE2, the second drain electrode DE2, the third source electrode SE3, the third drain electrode DE3 and the voltage-dividing reference line RL may include the same material and may be disposed on the same layer.

As shown in the exemplary embodiment of FIG. 2, the first data line DL1 and the second data line DL2 may extend substantially in the second direction DR2 and may be spaced apart from each other in the first direction DR1. The first data line DL1 may be electrically connected to the first switching element T1 and the second switching element T2 of one pixel, and the second data line DL2 may be electrically connected to switching elements of adjacent pixels.

A reference voltage for a dividing voltage may be applied to the reference line RL. The reference voltage applied to the reference line RL may be different from the common voltage applied to a common electrode to be described later. For example, in an exemplary embodiment, the voltage level of the reference voltage applied to the reference line RL may be greater than the voltage level of the common voltage.

As shown in the exemplary embodiment of FIG. 2, at least a portion of the reference line RL may be disposed in parallel with the first data line DL1 and the second data line DL2. The reference line RL may be disposed to overlap the first sub-pixel electrode 191 and the second sub-pixel electrode 192 (e.g., in a thickness direction of the first substrate SUB1), and may be disposed between the first data line DL1 and the second data line DL2 (e.g., in the first direction DR1) when viewed from the top. Each of the first data line DL1, the second data line DL2 and the reference line RL may be disposed on the first substrate SUB1 or may include a part in contact with the ohmic pattern OP. The reference line RL may intersect the scan line SL.

In the first switching element T1, the first source electrode SE1 may be electrically connected to the first data line DL1. One side of the first source electrode SE1 may be disposed on an ohmic contact layer OC, and may be electrically connected to the first semiconductor region AP1 of the semiconductor pattern APP. Another side of the first source electrode SE1 may be connected to the second source electrode SE2, which will be described later. As shown in the exemplary embodiment of FIG. 2, a portion of the first source electrode SE1 may have a curved shape such as U shape. The first drain electrode DE1 may be disposed on an ohmic contact layer OC, and may be electrically connected to the first semiconductor region AP1 of the semiconductor pattern APP. The first source electrode SE1 may be spaced apart from the first drain electrode DE1. Accordingly, the first switching element T1 may include the first gate electrode GEL, the first semiconductor region AP1, the first source electrode SE1, and the first drain electrode DE1.

In the second switching element T2, one side of the second source electrode SE2 may be electrically connected to the first data line DL1, and may be electrically connected to the first source electrode SE1. The second source electrode SE2 may be disposed on the second semiconductor region AP2 of the semiconductor pattern APP and may be electrically connected to the second semiconductor region AP2 through an ohmic contact layer OC. Another side of the second source electrode SE2 may be connected to the first source electrode SE1. The second drain electrode DE2 may be disposed on an ohmic contact layer OC and may be electrically connected to the second semiconductor region AP2 of the semiconductor pattern APP. The second source electrode SE2 may be spaced apart from the second drain electrode DE2. Accordingly, the second switching element T2 may include the second gate electrode GE2, the second semiconductor region AP2, the second source electrode SE2, and the second drain electrode DE2.

In the third switching element T3, one side of the third source electrode SE3 may be electrically connected to the reference line RL. The third source electrode SE3 may be disposed on an ohmic contact layer OC and may be electrically connected to the third semiconductor region AP3 of the semiconductor pattern APP. In an exemplary embodiment, the third source electrode SE3 may be a portion of the reference line RL. The third drain electrode DE3 may be disposed on an ohmic contact layer OC and may be electrically connected to the third semiconductor region AP3. The third drain electrode DE3 may be substantially identical to the second drain electrode DE2, or may be a portion of the second drain electrode DE2. For example, as shown in the exemplary embodiment of FIG. 3, the second drain electrode DE2 and the third drain electrode DE3 may be formed from one unitary electrode. However, exemplary embodiments of the present inventive concepts are not limited thereto. The third source electrode SE3 may be spaced apart from the third drain electrode DE3. Accordingly, the third switching element T3 may include the third gate electrode GE3, the third semiconductor region AP3, the third source electrode SE3, and the third drain electrode DE3.

The second metal layer M2 may be formed of a single layer or multiple layers. In an exemplary embodiment in which the second metal layer M2 is formed of a single layer, the second metal layer M2 may include one compound selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu) or an alloy thereof. When the second metal layer M2 is formed of multiple layers, the second metal layer M2 may be formed of double layers of copper/titanium or molybdenum/aluminum-neodymium, triple layers of titanium/aluminum/titanium, molybdenum/aluminum/molybdenum or molybdenum/aluminum-neodymium/molybdenum.

However, exemplary embodiments of the present inventive concepts are not limited thereto and the composition of the multiple layers of the second metal layer M2 may vary in other exemplary embodiments.

The first metal layer M1 may be spaced apart from the second metal layer M2. As described above, the first metal layer M1 may be formed in a undercut shape underneath the gate insulating pattern G1, and thus the second metal layer M2 extended to the same layer with the first metal layer M1 may be separated from the second metal layer M2. For example, there may be a pore between the first drain electrode DE1 and the first gate electrode GE1, so that the first drain electrode DE1 may be separated from the first gate electrode GE1.

A passivation layer ORL may be disposed over the first switching element T1, the second switching element T2 and the third switching element T3 formed on the first substrate SUB1. In an exemplary embodiment, the passivation layer ORL may form a flat surface and may include a material that has photosensitivity. A color filter CF is disposed between the second metal layer M2 and the passivation layer ORL (e.g., in a thickness direction of the first substrate SUB1). In an exemplary embodiment, the color of the color filter CF may be one of red, green, and blue. However, exemplary embodiments of the present inventive concepts are not limited thereto.

The color filter CF and the passivation layer ORL may include a first contact hole CH1 exposing a portion of the first drain electrode DE1 and a second contact hole CH2 exposing a portion of the second drain electrode DE2.

The first sub-pixel electrode 191 and the second sub-pixel electrode 192 may be disposed on the passivation layer ORL. As shown in the exemplary embodiment of FIG. 2, the first sub-pixel electrode 191 may be disposed substantially in the first sub-pixel area PA1, and the second sub-pixel electrode 192 may be disposed substantially in the second sub-pixel area PA2. The first sub-pixel electrode 191 may be in contact with the first drain electrode DE1 through the first contact hole CHI and may be electrically connected to it. The second sub-pixel electrode 192 may be in contact with the second drain electrode DE2 through the second contact hole CH2 and may be electrically connected to it.

The first sub-pixel electrode 191 may include a first stem electrode 191a disposed in the first sub-pixel area PA1, first branch electrodes 191b disposed in the first sub-pixel area PA1, extended outward from the first stem electrode 191a and spaced apart from one another with a slit 191c therebetween. The first sub-pixel electrode 191 also includes a first extended part 191d extended from the first sub-pixel area PA1 to the switching element area TA.

The first stem electrode 191a may include a horizontal stem part extended in the first direction DR1, and a vertical stem part extended in the second direction DR2. The first stem electrode 191a may divide the first sub-pixel pixel electrode 191 into subsidiary regions, such as domains. For example, as shown in the exemplary embodiment of FIG. 2, the first stem electrode 191a may be formed in a cross shape. However, exemplary embodiments of the present inventive concepts are not limited thereto and the first stem electrode 191a may have various different shapes. In the exemplary embodiment shown in FIG. 2, the first sub-pixel electrode 191 may be divided into four subsidiary regions by the first stem electrode 191a. The first branch electrodes 191b positioned in different subsidiary regions may be extended in different directions. For example, as shown in FIG. 2, the first branch electrodes 191b positioned in the upper right subsidiary region may extended obliquely (e.g., in a direction between the first direction DR1 and the second direction DR2) from the first stem electrode 191a in the upper right direction, while the first branch electrodes 191b positioned in the lower right subsidiary region may extend obliquely from the first stem electrode 191a in the lower right direction. The first branch electrodes 191b positioned in the upper left subsidiary region may extend obliquely from the first stem electrode 191a in the upper left direction, while the first branch electrodes 191b positioned in the lower left subsidiary region may extend obliquely from the first stem electrode 191a in the lower left direction. However, exemplary embodiments of the present inventive concepts are not limited thereto and the first branch electrodes 191b may be variously arranged in the different domains. The first extended pan 191d may extend from the first stem electrode 191a or the first branch electrodes 191b to the switching element area TA and may extend through the first contact hole CHI for electrically connection to the first drain electrode DE1. For example, as shown in the exemplary embodiment of FIG. 3, the first extended part 191d may extend through the first contact hole CHI and may directly contact the first drain electrode DE1.

The second sub-pixel electrode 192 may include a second stem electrode 192a disposed in the second sub-pixel area PA2, second branch electrodes 192b disposed in the second sub-pixel area PA2, extended outward from the second stem electrode 192a and spaced apart from one another with a slit 192c therebetween. The second sub-pixel electrode 192 also includes a second extended part 191d extended from the second sub-pixel area PA2 to the switching element area TA.

The second stem electrode 192a, the second branch electrodes 192b and the second extended part 192d are substantially identical to the first stem electrode 191a, the first branch electrodes 191b and the first extended part 191d, respectively; and, therefore, the redundant description will be omitted for convenience of explanation.

In an exemplary embodiment, the first sub-pixel electrode 191 and the second sub-pixel electrode 192 may include a transparent material to allow light to transmit therethrough. For example, the first sub-pixel electrode 191 and the second sub-pixel electrode 192 may be formed of indium tin oxide (ITO), indium zinc oxide (IZO), or indium tin zinc oxide (ITZO). However, exemplary embodiments of the present inventive concepts are not limited thereto. For example, in other exemplary embodiments, the first sub-pixel electrode 191 and the second sub-pixel electrode 192 may be formed of any other material that is transparent and conductive.

As shown in the exemplary embodiment of FIG. 3, the first metal layer M1 may include a storage line 127. A holding voltage may be applied to the storage line 127. For example, in an exemplary embodiment, the holding voltage may be identical to the common voltage applied to the common electrode. However, exemplary embodiments of the present inventive concepts are not limited thereto. For example, in another exemplary embodiment, the holding voltage may have the voltage level equal to the voltage applied to the reference line RL.

As shown in the exemplary embodiment of FIG. 2, the storage line 127 may include a first part 128 extended in the first direction DR1 and parallel to the scan line SL, and a second part 129 extended in the second direction DR2 from the first part 128 and disposed adjacent to both sides (e.g., upper and lower sides in the second direction DR2) of the first sub-pixel electrode 191.

In an exemplary embodiment, the second part 129 of the storage line 127 may overlap the first sub-pixel electrode 191 (e.g., in a thickness direction of the first substrate SUB1). However, exemplary embodiments of the present inventive concepts are not limited thereto. For example, in another exemplary embodiment, the second part 129 of the storage line 127 may not overlap the first sub-pixel electrode 191. The second part 129 may function as a light-blocking pattern that prevents light transmission on the both sides of the first sub-pixel electrode 191. The first part 128 of the storage line 127 may overlap the first drain electrode DE1 (e.g., in a thickness direction of the first substrate SUB1) to form a holding capacitance in the first sub-pixel area PA1.

The storage line 127 may be electrically connected to the reference line RL. According to an exemplary embodiment of the present inventive concepts, the reference line RL may be electrically connected to the storage line 127 to commonly distribute the reference voltage to adjacent pixels. For example, in an exemplary embodiment in which the plurality of sub-pixels SP includes a red sub-pixel, a green sub-pixel and a blue sub-pixel, the reference line RL may be disposed in the blue sub-pixel, and a voltage may be distributed to the adjacent red sub-pixel and green sub-pixel through the storage line 127 connected to the reference line RL in the blue sub-pixel. In this exemplary embodiment, the voltage at the reference line RL may be equal to the voltage at the storage line 127.

As shown in the exemplary embodiments of FIGS. 2 and 3, the storage line 127 may be in contact with the reference line RL through a third contact hole CH3. The third contact hole CH3 may penetrate through layers disposed between the storage line 127 and the reference line RL. For example, the third contact hole CH3 may penetrate through the gate insulating pattern GI, the semiconductor pattern APP and the ohmic pattern OP to expose the storage line 127 of the first metal layer M1. As shown in the exemplary embodiment of FIG. 3, the storage line 127 may directly contact the reference line RL through the third contact hole CH3 without any additional bridge pattern for electrical connection thereto. In contrast, two contact holes are required when a bridge pattern is used. Therefore, it is possible to reduce the number of the contact hole and thus reduce the total area of the contact holes. Therefore, the configuration may improve the aperture ratio of the pixels. Although the storage line 127 of the first metal layer and the reference line RL of the second metal layer are directly connected with each other without any bridge pattern in the exemplary embodiment shown in FIG. 3, the first metal layer and the second metal layer may also be directly connected with each other in the gate drivers or the electrostatic discharge part, for example. Accordingly, the total area of the contact holes may be reduced also in the gate drivers or the electrostatic discharge part.

As shown in the exemplary embodiment of FIG. 3, the second substrate SUB2 facing the first substrate SUB1 may include a light-blocking member BM, an overcoat layer OCL, and a common electrode CE.

In an exemplary embodiment, the second substrate SUB2 may be a transparent insulating substrate similar to the first substrate SUB1. In addition, the second substrate SUB2 may include a polymer or plastic having high beat resistance. The second substrate SUB2 may have flexibility. However, exemplary embodiments of the present inventive concepts are not limited thereto.

The light-blocking member BM may be disposed on a surface of the second substrate SUB2 facing the first substrate SUB1. The light-blocking member BM may overlap the switching element area TA (e.g., in a thickness direction of the first substrate SUB1). The light-blocking member BM may include a light-blocking pigment such as carbon black or an opaque material such as chromium (Cr), and may include a photosensitive organic material. However, exemplary embodiments of the present inventive concepts are not limited thereto. For example, the light-blocking member BM may be disposed in the first substrate SUB1 in other exemplary embodiments.

The overcoat layer OCL may be formed on a surface of the second substrate SUB2 to cover the light-blocking member BM. The overcoat layer OCL may provide a flat surface over the level difference created by the light-blocking member BM. However, exemplary embodiments of the present inventive concepts are not limited thereto and the overcoat layer OCL may be eliminated in other exemplary embodiments.

The common electrode CE may be disposed on the overcoat layer OCL. In exemplary embodiments in which the overcoat layer OCL is eliminated, the common electrode CE may be disposed on the second substrate SUB2 and the light-blocking member BM. In an exemplary embodiment, the common electrode CE may include a transparent conductive material, such as indium tin oxide (ITO), indium zinc oxide (IZO), or indium tin zinc oxide (ITZO), like the sub-pixel electrode described above. However, exemplary embodiments of the present inventive concepts are not limited thereto. In an exemplary embodiment, the common electrode CE may be formed over the entire surface of the second substrate SUB2. A common voltage is applied to the common electrode CE to form an electric field together with the first sub-pixel electrode 191 and the second sub-pixel electrode 192. In such case, the alignment of the liquid-crystal molecules in a liquid-crystal layer 300 is changed according to the magnitude of the electric field, so that the light transmittance can be controlled.

The liquid-crystal layer 300 may be disposed between the first substrate SUB1 and the second substrate SUB2. The liquid-crystal layer 300 may include liquid-crystal molecules having dielectric anisotropy. When an electric field is applied between the first substrate SUB1 and the second substrate SUB2, the liquid-crystal molecules rotate in a direction between the first substrate SUB1 and the second substrate SUB2 to thereby adjust the phase retardation of the light passing through the liquid-crystal layer 300. The amount of the polarized light (e.g., the light having passed through a lower polarizer) that passes through an upper polarizer (which may be disposed on the exit side and, for example, may be attached to an outer surface of the second substrate) varies depending on a change in the phase retardation by the rotation of the liquid-crystal molecules. Based on this, it is possible to control the transmittance.

A pixel according to another exemplary embodiment shown in FIG. 4 is different from the pixel shown in the exemplary embodiment of FIG. 2 in that a first contact hole CH1, a second contact hole CH2, and a third contact hole CH3 overlap the storage line 127. In this exemplary embodiment, the aperture ratio may be improved by reducing the width of the switching element area TA. Additionally, the pixel shown in the exemplary embodiment of FIG. 4 differs from the pixel shown in the exemplary embodiment of FIG. 3 in that the first switching element T1 is connected to the second sub-pixel electrode 192 and the second switching element T2 is connected to the first sub-pixel electrode 191. The other configurations of the exemplary embodiment of FIG. 4 are identical to those described above with respect to the exemplary embodiments of FIGS. 2-3 and a redundant description will be omitted for convenience of explanation.

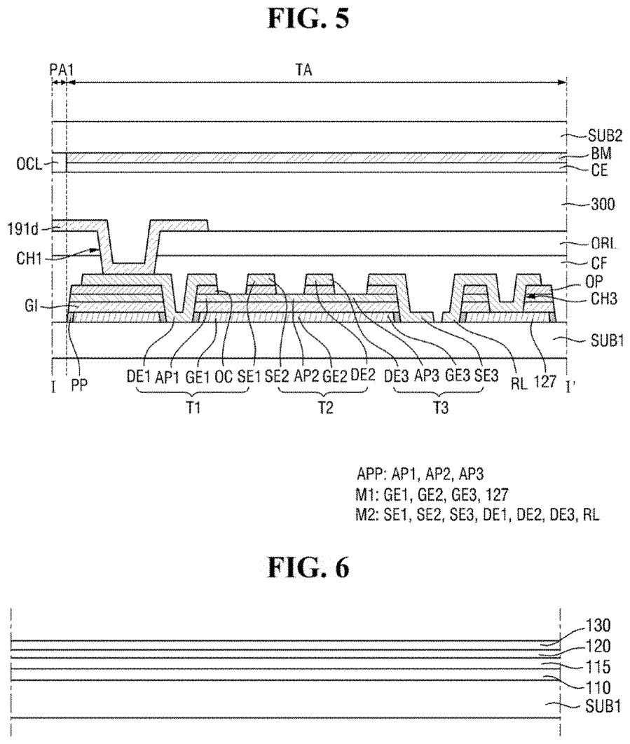

FIG. 5 is a cross-sectional view showing a pixel of a display device according to another exemplary embodiment of the present inventive concepts. FIG. 5 shows a structure according to another exemplary embodiment, taken along line I-I′ of FIG. 2. Like reference numerals to those used in FIG. 3 denote like elements, and redundant descriptions of such elements will not be repeated for convenience of explanation.

Referring to the exemplary embodiment of FIG. 5, a first metal layer M1 may be disposed on the first substrate SUB1. The first metal layer M1 may include a plurality of first metal parts, including a first gate electrode GE1, a second gate electrode GE2, a third gate electrode GE3 and a storage line 127. In an exemplary embodiment, the first gate electrode GE1, the second gate electrode GE2, the third gate electrode GE3 and the storage line 127 may be disposed on the same layer and may include the same material. The first gate electrode GE1, the second gate electrode GE2 and the third gate electrode GE3 may be electrically connected to the scan line, and the storage line 127 may be electrically connected to the reference line RL. The first gate electrode GE1, the second gate electrode GE2, and the third gate electrode GE3 may be connected with one another. For example, as shown in the exemplary embodiment of FIG. 5, the first gate electrode GE1, the second gate electrode GE2, and the third gate electrode GE3 may be formed of a unitary electrode. However, exemplary embodiments of the present inventive concepts are not limited thereto.

A gate insulating pattern GI may be disposed on the first metal layer M1. For example, the gate insulating pattern GI may be disposed on the first gate electrode GE1, the second gate electrode GE2, the third gate electrode GE3 and the storage line 127 to insulate them from one another. A semiconductor pattern APP may be disposed on the gate insulating pattern GI. The semiconductor pattern APP may include a first semiconductor region AP1, a second semiconductor region AP2, and a third semiconductor region AP3. The first semiconductor region AP1 may overlap the first gate electrode GE1, the second semiconductor region AP2 may overlap the second gate electrode GE2, and the third semiconductor region AP3 may overlap the third gate electrode GE3.

An ohmic pattern OP may be disposed on the semiconductor pattern APP. The ohmic pattern may include ohmic contact layers OC that are spaced apart from each other on the first semiconductor region AP1, the second semiconductor region AP2 and the third semiconductor region AP3, respectively.

A second metal layer M2 may be disposed on the first substrate SUB1, the ohmic contact layers OC and the ohmic pattern OP. As shown in the exemplary embodiment of FIG. 5, the second metal layer M2 may include a plurality of second metal parts, including a first source electrode SE1, a first drain electrode DE1, a second source electrode SE2, a second drain electrode DE2, a third source electrode SE3, a third drain electrode DE3 and a voltage-dividing reference line RL. In an exemplary embodiment, the first source electrode SE1, the first drain electrode DE1, the second source electrode SE2, the second drain electrode DE2, the third source electrode SE3, the third drain electrode DE3 and the voltage-dividing reference line RL may be formed of the same material and may be disposed on the same layer.

The first switching element T1 may include the first gate electrode GE1, the first semiconductor region AP1, the first source electrode SE1, and the first drain electrode DEL. The second switching element T2 may include the second gate electrode GE2, the second semiconductor region AP2, the second source electrode SE2, and the second drain electrode DE2. The third switching element T3 may include the third gate electrode GE3, the third semiconductor region AP3, the third source electrode SE3, and the third drain electrode DE3.

A color filter CF may be disposed over the first switching element T1, the second switching element T2 and the third switching element T3 formed on the first substrate SUB1. A passivation layer ORL may be disposed on the color filter CF. The color filter CF and the passivation layer ORL may include a first contact hole CHI exposing a portion of the first drain electrode DE1.

The first sub-pixel electrode 191, such as the first extended part 191d, may be disposed on the passivation layer ORL. The first sub-pixel electrode 191 may be mostly disposed in the first sub-pixel area PA1. For example, as shown in the exemplary embodiment of FIG. 5, the first sub-pixel electrode 191 may not extend to the second or third switching elements T2, T3. The first extended part 191d of the first sub-pixel electrode 191 extends through the first contact hole CH1 and may directly contact the first drain electrode DE1 for electrical connection thereto.

The storage line 127 may be disposed on the first substrate SUB1 and may be spaced apart from the first to third switching elements T1, T2, and T3. The storage line 127 may be electrically connected to the reference line RL. The storage line 127 and the reference line RL may be in contact with each other through a third contact hole CH3 penetrating through the gate insulating pattern GI, the semiconductor pattern APP and the ohmic pattern OP and exposing the storage line 127 of the first metal pattern M1. As shown in the exemplary embodiment of FIG. 5, the storage line 127 may be connected directly to the reference line RL through the third contact hole CH3 without any additional bridge pattern. In contrast, two contact holes are required when a bridge pattern is used. Therefore, it is possible to reduce the number of the contact hole and thus reduce the total area of the contact holes. Therefore, this configuration may improve the aperture ratio of the pixels.

The second substrate SUB2 facing the first substrate SUB1 may include a light-blocking member BM, an overcoat layer OCL, and a common electrode CE. For example, as shown in the exemplary embodiment of FIG. 5, a light-blocking member BM may be disposed on a surface of the second substrate SUB2. The overcoat layer OCL may be formed on a surface of the second substrate SUB2 to cover the light-blocking member BM. The common electrode CE may be disposed on the overcoat layer OCL. In an exemplary embodiment, the common electrode CE may be formed over the entire surface of the second substrate SUB2. The liquid-crystal layer 300 may be disposed between the first substrate SUB1 and the second substrate SUB2.

The display device according to the exemplary embodiment of FIG. 5 may include organic film patterns PP disposed outside the lateral side surfaces of the first metal parts of the first metal layer M1.

For example, the first metal layer M1 may include the first metal parts including the first to third gate electrodes GE1, GE2 and GE3 and the storage line 127 as described above. The organic film patterns PP may directly contact lateral side surfaces of each of the first metal parts of the first metal layer M1. For example, the organic film patterns PP may directly contact at least one lateral edge of each of the first to third gate electrodes GE1, GE2 and GE3, and at least one lateral edge of the storage line 127. According to this exemplary embodiment, since the first to third gate electrodes GE1, GE2 and GE3 are implemented as a single gate pattern, the organic film patterns PP may be disposed to contact at least one lateral edge of the gate pattern. The organic film patterns PP may also be in contact with at least one side (e.g., a lateral edge) of the scan line. As shown in the exemplary embodiment of FIG. 5, the organic film patterns PP are disposed on the both lateral edges of each element (e.g., the first to third gate electrodes GE1, GE2 and GE3 and the storage line 127) of the first metal layer M1.

As shown in the exemplary embodiment of FIG. 5, each portion of the gate insulating pattern GI disposed on a first metal part of the first metal layer M1 may have a width that is larger than the width of the first metal part of the first metal layer M1 thereunder. Therefore, the lateral side surfaces of the gate insulating pattern GI protrude from the lateral edges of each first metal part of the first metal layer M1 that the gate insulating pattern is disposed thereon and the lateral side surfaces of the gate insulating pattern GI may at least partially overlap the organic film pattern PP thereunder. For example, the first metal layer M1 may be formed in an undercut shape underneath the gate insulating pattern GI in which the portion of the gate insulating pattern GI above each first metal part of the first metal layer M1 extends farther than the lateral edges of the first metal part of the first metal layer M1 thereunder. The organic film patterns PP may be disposed in the undercut shape and may be positioned adjacent to the lateral edges of the first metal layer M1. For example, the organic film patterns PP may be positioned under the portions of the gate insulating pattern G1 protruding from the lateral edges of a first metal part of the first metal layer M1. The outer lateral edges of the organic film patterns PP may be aligned with the lateral edges of the gate insulating pattern GI. For example, the outer lateral edges of the organic film patterns PP may be coordinated or disposed on the same line with the lateral edges of the gate insulating pattern GI. In an exemplary embodiment, one or more of the organic film patterns PP may protrude from lateral edges of the gate insulating pattern GI that is disposed on the organic film pattern PP.

As shown in the exemplary embodiment of FIG. 5, each of the organic film patterns PP may directly contact one lateral edge of a first metal part of the first metal layer M1 and each first metal part of the first metal layer M1 may have a different organic film pattern PP contacting each lateral edge. An upper surface of each of the organic film patterns PP may directly contact lower surfaces of the gate insulating pattern G1 that protrude from the first to third gate electrodes GE1, GE2 and GE3 or the storage line 127. However, exemplary embodiments of the present inventive concepts are not limited thereto. For example, in another exemplary embodiment, one of the organic film patterns PP may be disposed to contact both lateral edges of the first to third gate electrodes GE1, GE2 and GE3 and may contact the lower side of the gate insulating pattern GI disposed on the first to third gate electrodes GE1, GE2 and GE3. In addition, one of the organic film patterns PP may directly contact both lateral edges of the storage line 127 and may directly contact the lower side of the gate insulating pattern GI disposed on the storage line 127.

The organic film patterns PP may be disposed in contact with one side of the second metal layer M2. The second metal layer M2 may be disposed on the ohmic pattern OP. A portion of the second metal layer M2 may extend downwardly to contact lateral edges of the ohmic pattern OP, the semiconductor pattern APP and the gate insulating pattern G1 and to contact an upper surface of the first substrate SUB1. The portion of the second metal layer M2 contacting the upper surface of the first substrate SUB1 may be positioned at the same level as the first metal layer M1. The first metal layer M1 and the second metal layer M2 positioned at the same level as each other may be electrically insulated from each other by the organic film patterns PP. As described above, the second metal layer M2 may include second metal parts including the first to third source electrodes SE1, SE2 and SE3, the first to third drain electrodes DE1, DE2 and DE3, the reference line RL, and the first data line.

For example, the first drain electrode DEI may be in contact with sides of the ohmic contact layer OC, the semiconductor pattern APP including first to third semiconductor regions AP1, AP2 and AP3, the gate insulating pattern GI, and a first organic film pattern of the organic film patterns PP. The third source electrode SE3 spaced apart from the first drain electrode DE1 may be in contact with sides of the ohmic contact layer OC, the semiconductor pattern APP including first to third semiconductor regions AP1, AP2 and AP3, the gate insulating pattern GI, and a second organic film pattern of the organic film patterns PP. In addition, the reference line RL may be in contact with lateral edges of the ohmic pattern OP, the semiconductor pattern APP, the gate insulating pattern GI and a third organic film pattern of the organic film patterns PP.

The organic film patterns PP may be disposed between the first metal layer M1 and the second metal layer M2. For example, as shown in the exemplary embodiment of FIG. 5, a first organic film pattern of the organic film patterns PP may be disposed between the first drain electrode DE1 and the first to third gate electrodes GE1, GE2 and GE3. A second organic film pattern of the organic film patterns PP may be disposed between the third source electrode SE3 and the first to third gate electrodes GE1, GE2 and GE3. A third organic film pattern of the organic film patterns PP may be disposed between the reference line RL and the storage line 127.

In an exemplary embodiment, each of the organic film patterns PP that are disposed between the first metal layer M1 and the second metal layer M2 may have a first side that directly contacts the first metal layer M1 and an opposite second side that directly contacts the second metal layer M2. The first metal layer M1 and the second metal layer M2 may be electrically insulated from each other by the organic film patterns PP.

For example, a first side of the first organic film pattern of the organic film patterns PP may directly contact a first side of the first to third gate electrodes GE1, GE2 and GE3, and the opposite second side of the first organic film pattern may directly contact the first drain electrode DE1. In addition, a first side of the second organic film pattern of the organic film patterns PP may directly contact the opposite second side of the first to third gate electrodes GE1, GE2 and GE3, and the second side of the second organic film pattern may directly contact the third source electrode SE3. In addition, a first side of a third organic film pattern of the organic film patterns PP may directly contact a first side of the storage line 127 and the opposite second side of the third organic film pattern may directly contact the reference line RL. In an exemplary embodiment, the organic film pattern PP disposed on the opposite second side of the storage line 127 may not be in contact with the second metal layer M2 and may be spaced apart therefrom.

In an exemplary embodiment, the organic film patterns PP may be formed of a photosensitive organic material or a non-photosensitive organic material. For example, the photosensitive organic material may be a photoresist. The non-photosensitive organic material may include polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP) or a combination thereof.

According to this exemplary embodiment, the display device includes the organic film patterns between the first metal layer and the second metal layer, thereby preventing the first metal layer and the second metal layer from being in contact with each other to prevent a short-circuit therefrom. Further, by filling the pores between the first metal layer and the second metal layer with the organic film patterns, it is possible to prevent corrosion of the first metal layer during the process.

Hereinafter, a method of fabricating the display device shown in FIG. 5 will be described. A method of fabricating the first substrate SUB1 exhibiting the features of the above-described exemplary embodiment will be illustrated.

FIGS. 6 to 15 are cross-sectional views showing steps of a method of fabricating a display device according to exemplary embodiments of the present inventive concepts.

Referring to the exemplary embodiment of FIG. 6, a first metal material layer 110, a gate insulating material layer 115, a first semiconductor material layer 120 and a second semiconductor material layer 130 are consecutively stacked on the first substrate SUB1 in this order.

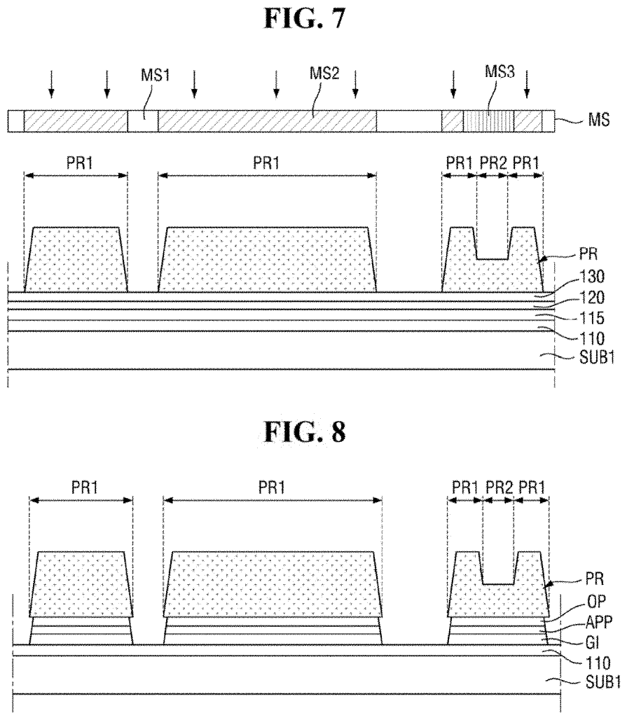

Referring to the exemplary embodiment of FIG. 7, a photoresist is applied onto the second semiconductor material layer 130. In an exemplary embodiment, the photoresist may be formed using a solution coating method such as spin coating, to form a photoresist layer. The photoresist pattern PR is formed by exposing and developing the photoresist layer using a first mask.

For example, the first mask MS, which is a half-tone mask, is aligned above a photoresist layer. The first mask includes a transmissive region MS1 through which light is transmitted, a non-transmissive region MS2 through which light is blocked, and a semi-transmissive region M3 through which the amount of light that is transmitted is adjusted. An exposure process of irradiating UV toward the substrate 1 from above the first mask MS is then performed. The first mask MS is placed so that the non-transmissive region M2 is in line (e.g., overlaps in the thickness direction of the first substrate SUB1) with regions where the gate electrode, the semiconductor pattern, the ohmic pattern and the storage line are to be formed. The semi-transmissive region M3 is in line with regions where the third contact hole via which the storage line contacts the reference line is to be formed. The transmissive region M1 is in line with the remaining regions. Accordingly, the regions in line with the non-transmissive region M2 are not irradiated with UV, the regions in line with the transmissive region MS1 are irradiated with UV, and the regions in line with the semi-transmissive region MS3 are irradiated with the adjusted amount of UV.

A developing solution is then applied onto the exposed photoresist layer to perform a developing process, so that a photoresist pattern PR is formed. According to the developing process, a first photoresist region PR1 having a first thickness is formed in the regions on the third metal layer 148a where the source electrode, the drain electrode and the data line are to be formed, and a second photoresist region PR2 having a second thickness smaller than the first thickness is formed in the regions where the third contact hole is to be formed. In the remaining regions, the photoresist layer is completely removed so that the second semiconductor material layer 130 is exposed. While the exemplary embodiment shows a positive photoresist pattern, exemplary embodiments of the present inventive concepts are not limited thereto and a negative photoresist pattern may be used in other exemplary embodiments.

Referring to the exemplary embodiment of FIG. 8, dry etching is carried out on regions other than the first photoresist region PR1 and the second photoresist region PR2, to remove the gate insulating material layer 15, the first semiconductor material layer 120, and the second semiconductor material layer 130. Accordingly, the gate insulating patterns GI, the semiconductor pattern APP and the ohmic pattern OP may be formed under the first photoresist region PR1 and the second photoresist region PR2.

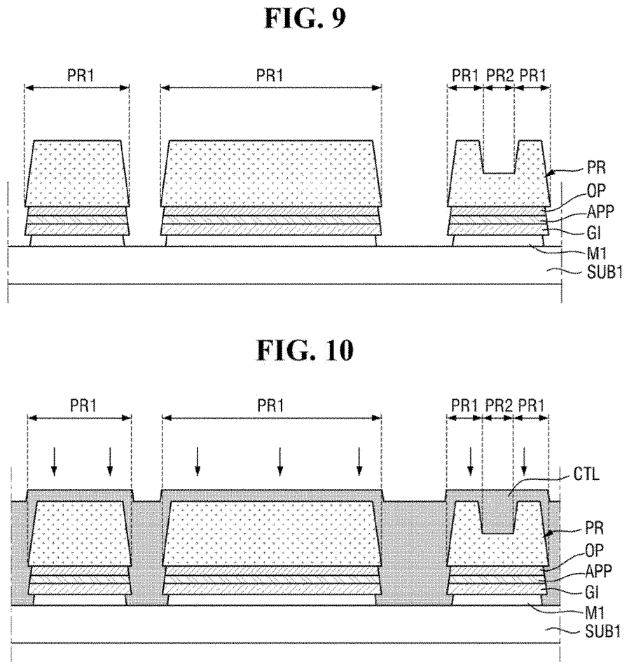

Referring to the exemplary embodiment of FIG. 9, the first metal material layer 110 is wet etched using the photoresist pattern PR as a mask, to form a first metal layer M1. As shown in the exemplary embodiment of FIG. 9, the first metal layer M1 may be over-etched during the wet etching process so that it is formed in an undercut shape underneath the gate insulating pattern GI.

Referring to the exemplary embodiment of FIG. 10, an organic coating layer CTL is coated over the photoresist pattern PR formed on the first substrate SUB1 and directly contacts the regions which were in line with the transmissive region M1. In an exemplary embodiment, the organic coating layer CTL may be a photosensitive organic material, such as a photoresist. UV exposure is carried out on the entire first substrate SUB1 after the organic coating layer CTL is formed thereon.

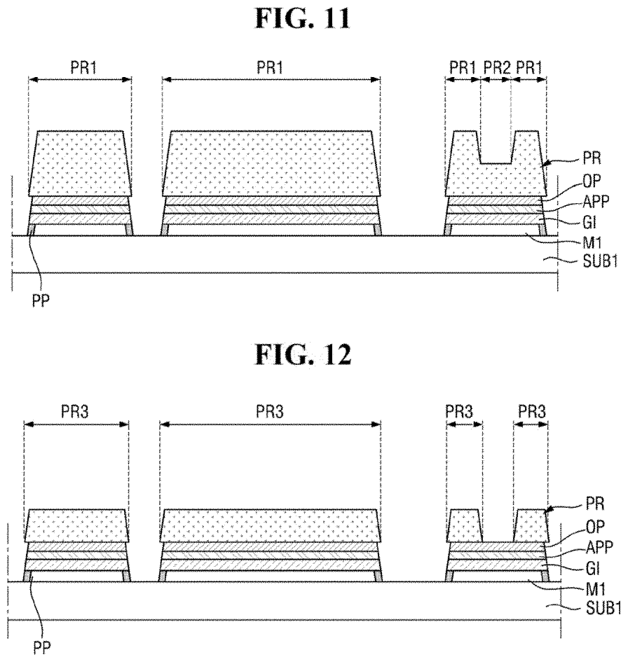

Referring to the exemplary embodiment of FIG. 11, the organic coating layer CTL exposed to UV is developed to form organic film patterns PP. For example, the gate insulating pattern GI, the semiconductor pattern APP, the ohmic pattern OP and the photoresist pattern PR disposed above the first metal layer M1 function as a mask, during the UV exposure on the organic coating layer CTL. The portions of the organic coating layer CTL which are formed in the undercut underneath the gate insulating pattern GI are not exposed to UV. Therefore, when the organic coating layer CTL is exposed to UV and is developed, organic film patterns PP may be formed on both sides of the first metal layer M1. For example, the organic film patterns PP may be formed on lateral edges of the first metal layer M1.

According to this exemplary embodiment, by forming the organic film patterns PP using a photosensitive organic material, the fabrication cost may be reduced as no additional mask is required.

Referring to the exemplary embodiment of FIG. 12, an ashing process is carried out on the photoresist pattern PR remaining on the first substrate SUB1. Ashing is carried out to reduce the thickness and area of the first photoresist region PR1 and also to remove the second photoresist region PR2 having the second thickness. Accordingly, after the ashing process, the second photoresist region PR2 having the second thickness is removed, and the thickness of the first photoresist region PR1 is reduced, to form the third photoresist region PR3 having a third thickness. As the second photoresist region PR2 is removed, the ohmic pattern OP under the second photoresist region PR2 may be exposed.

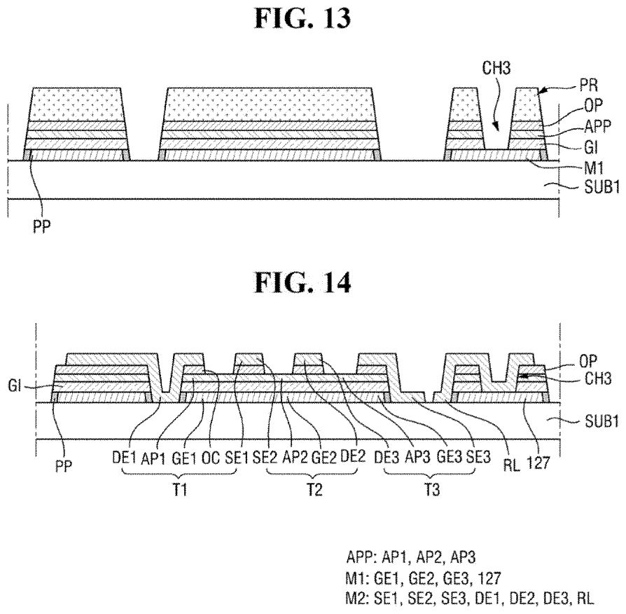

Referring to the exemplary embodiment of FIG. 13, dry etching is performed on the first substrate SUB1 using the third photoresist region PR3 of the photoresist pattern PR as a mask, to form a third contact hole CH3.

For example, the portions of the ohmic pattern OP and the semiconductor pattern APP and the gate insulating pattern GI under the ohmic pattern OP which do not overlap the third photoresist region PR3 of the photoresist pattern PR are removed altogether by dry etching, so that a third contact hole CH3 exposing the first metal layer M1 is formed.

Referring to the exemplary embodiment of FIG. 14, residuals of the photoresist pattern PR remaining on the first substrate SUB1 are stripped and removed. Accordingly, the first metal layer M1 may include the first metal parts comprising the first to third gate electrodes GE1, GE2 and GE3 and the storage line 127, and the semiconductor pattern APP may include the first to third semiconductor regions AP1 and AP2 and AP3, and the ohmic pattern OP may include the ohmic contact layers OC.

A second metal material layer is then stacked on the first substrate SUB1 and etched using a second mask to form a second metal layer M2. The second metal layer M2 may include the second metal parts, including the first to third source electrodes SE), SE2 and SE3, the first to third drain electrodes DE1, DE2 and DE3, and the reference line RL.

For example, the first drain electrode DE1 is formed on the ohmic contact layers OC, and may function as a drain electrode of the first semiconductor region AP1. The first source electrode SE1 is formed on the ohmic contact layers OC formed between the first semiconductor region AP1 and the second semiconductor region AP2, so that it may function as the first source electrode SE1 of the first semiconductor region AP1 and as the second source electrode SE2 of the second semiconductor region AP2. The second drain electrode DE2 may be formed on the ohmic contact layers OC formed between the second semiconductor region AP2 and the third semiconductor region AP3, so that it may function as the second drain electrode DE2 of the second semiconductor region AP2 and as the third drain electrode DE3 of the third semiconductor region AP3. The third source electrode SE3 may be formed on the ohmic contact layers OC formed on the third semiconductor region AP3 and may function as the third source electrode SE3 of the third semiconductor region AP3. The reference line RL may directly contact the storage line 127 through the third contact hole CH3.

Accordingly, the first switching element T1 may include the first gate electrode GE1, the first semiconductor region AP1, the first source electrode SE1, and the first drain electrode DEI. The second switching element T2 may include the second gate electrode GE2, the second semiconductor region AP2, the second source electrode SE2, and the second drain electrode DE2. The third switching element T3 may include the third gate electrode GE3, the third semiconductor region AP3, the third source electrode SE3, and the third drain electrode DE3.

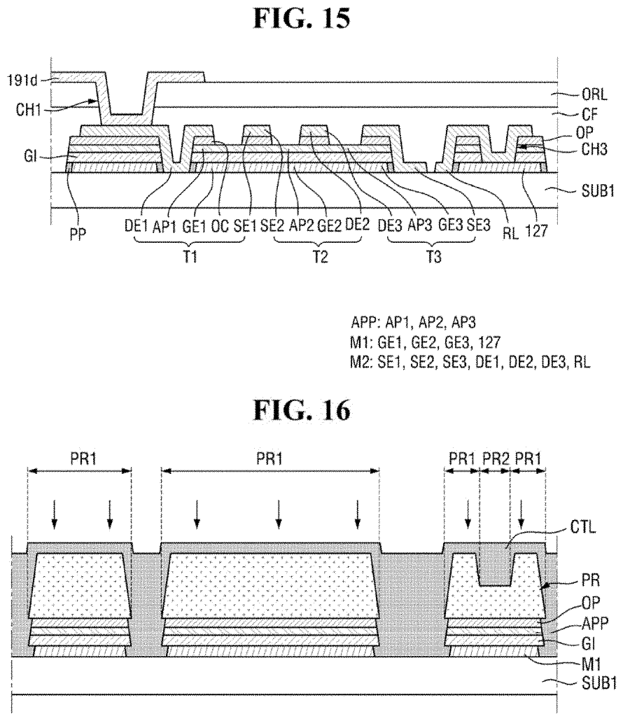

Referring to the exemplary embodiment of FIG. 15, a color filter CF is formed over the first to third switching elements T1, T2 and T3 formed on the first substrate SUB1 and then a passivation layer ORL is formed on the color filter CF. A third mask is aligned above the passivation layer ORL, a first contact hole CH1 exposing the first drain electrode DE1 is formed by patterning the color filter CF and the passivation layer ORL. The second contact hole CH2 shown in FIG. 2 may also be formed at the same time.

A conductive material layer is then formed on the first substrate SUB1 and patterned using a fourth mask to form a first sub-pixel electrode 191 including a first extended part 191d. Accordingly, the first substrate SUB1 of the display device according to an exemplary embodiment of the present inventive concepts may be produced.

As described above, the method of the fabricating the display device according to an exemplary embodiment of the present inventive concepts has the advantage that no additional mask is required by forming the organic film patterns using the photosensitive organic material to thereby reduce the fabrication cost. In addition, according to an exemplary embodiment of the present inventive concepts, the display device includes the organic film patterns between the first metal layer and the second metal layer, thereby preventing the first metal layer and the second metal layer from contacting each other to prevent a short-circuit. Further, by filling the pores between the first metal layer and the second metal layer with the organic film patterns, it is possible to prevent corrosion of the first metal layer.

Hereinafter, a method of fabricating a display device according to another exemplary embodiment of the present inventive concepts will be described. A description of elements that are substantially identical to previously described elements will be omitted for convenience of explanation.

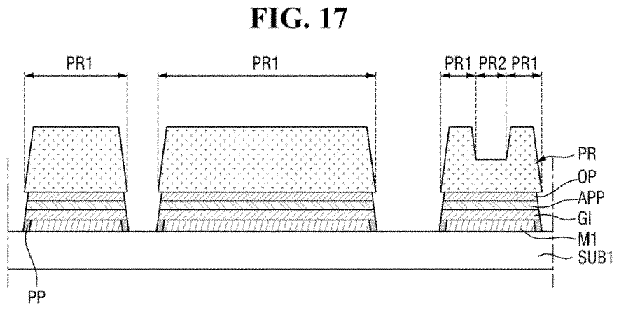

FIGS. 16 and 17 are cross-sectional views showing processing steps of a method of fabricating a display device according to another exemplary embodiment of the present inventive concepts. Some of the processing steps according to this exemplary embodiment are substantially identical to the processing steps described above with respect to the exemplary embodiments of FIGS. 6 to 9; and, therefore, a redundant description will be omitted for convenience of explanation.

Referring to the exemplary embodiment of FIG. 16, an organic coating layer CTL is coated over the photoresist pattern PR formed on the first substrate SUB1. For example, in an exemplary embodiment, the organic coating layer CTL may include, as the non-photosensitive organic material, polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP) or a combination thereof.

A dry etching process is then performed on the entire first substrate SUB1 after the organic coating layer CTL is formed thereon.

Referring to the exemplary embodiment of FIG. 17, the organic coating layer CTL is dry etched to form an organic film patterns PP. For example, the gate insulating pattern GI, the semiconductor pattern APP, the ohmic pattern OP and the photoresist pattern PR disposed above the first metal layer M1 function as a mask, during the dry etching on the organic coating layer CTL. The portions of the organic coating layer CTL which are formed in the undercut underneath the gate insulating pattern GI are not etched. Therefore, when the organic coating layer CTL is dry etched, organic film patterns PP may be formed on both sides of the first metal layer M1. For example, the organic film patterns PP may be formed on lateral edges of the first metal layer M1.

The subsequent processes are identical to those described above with respect to the exemplary embodiments of FIGS. 12 to 15; and, therefore, the redundant description will be omitted for convenience of explanation.

According to this exemplary embodiment, by coating a non-photosensitive organic material and dry etching it to form the organic film patterns PP, no additional mask is required and the fabrication cost may be reduced.

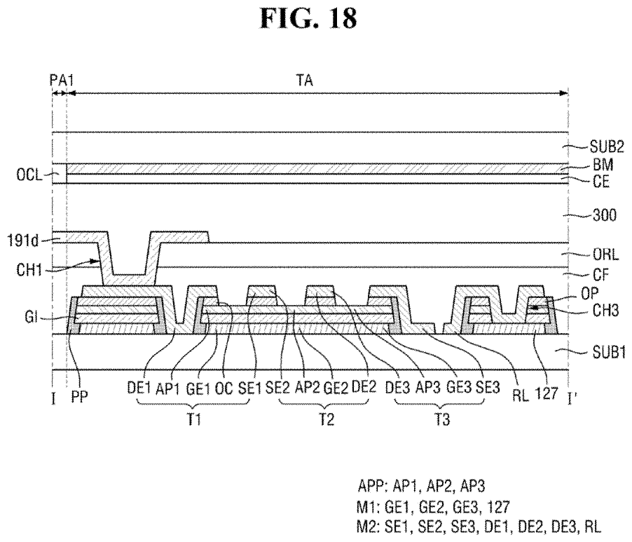

FIG. 18 is a cross-sectional view of a pixel of a display device according to another exemplary embodiment of the present inventive concepts. FIG. 18 shows a structure according to another exemplary embodiment, taken along line I-I′ of FIG. 2. This exemplary embodiment is substantially identical to the exemplary embodiment of FIG. 5 except for the configuration of the organic film patterns PP; and, therefore, a redundant description of substantially identical elements will be omitted for convenience of explanation.

Referring to FIG. 18, the display device according to this exemplary embodiment may include organic film patterns PP that directly contact at least one side of each of the first metal layer M1, the gate insulating pattern GI, the semiconductor pattern APP, and the ohmic pattern OP.

For example, as shown in the exemplary embodiment of FIG. 18, the first metal layer M1 may include first metal parts including the first to third gate electrodes GE1, GE2 and GE3 and the storage line 127. The organic film patterns PP may be in contact with at least one side of the first to third gate electrodes GE1, GE2 and GE3, and at least one side of the storage line 127. For example, each of the organic film patterns PP may extend upwardly from the level of the first metal layer M1 to contact lateral edges of the first to third gate electrodes GE1, GE2 and GE3 and at least one lateral edge of the storage line 127. According to this exemplary embodiment, since the first to third gate electrodes GE1, GE2 and GE3 are implemented as the single gate pattern, the organic film patterns PP may be disposed in contact with at least one lateral edge of the gate pattern. As shown in the exemplary embodiment of FIG. 18, the organic film patterns PP are disposed on the both lateral edges of the first metal layer M1.

The gate insulating pattern GI disposed on the first metal layer M1 may have a width that is larger than the width of the first metal layer M1. Therefore, the lateral side surfaces of the gate insulating pattern GI protrude from the lateral edges of the first metal layer M1, respectively. For example, the first metal layer M1 may be formed in an undercut shape underneath the gate insulating pattern GI. The organic film patterns PP may be disposed in the undercut shape between the first metal layer M1 and the gate insulating pattern GI. The outer lateral surfaces of the organic film patterns PP may protrude from the lateral side surfaces of the gate insulating pattern GI.

In an exemplary embodiment, the organic film patterns PP may directly contact both lateral edges of the first metal layer M1 and the lower side of the gate insulating pattern GI. For example, one of the organic film patterns PP may be disposed in direct contact with both lateral edges of the first to third gate electrodes GE1, GE2 and GE3, and may directly contact the lower side of the gate insulating pattern GI disposed on the first to third gate electrodes GE1, GE2 and GE3. In addition, one of the organic film patterns PP may be disposed in direct contact with both lateral edges of the storage line 127 and may be disposed in direct contact with the lower side of the gate insulating pattern GI disposed on the storage line 127.

In addition, the organic film patterns PP may be disposed in contact with at least one side of the gate insulating pattern GI. For example, a first organic film pattern of the organic film patterns PP may be in contact with a first lateral edge of the gate insulating pattern GI, and a second organic film pattern of the organic film patterns PP may be in contact with an opposite second lateral edge of the gate insulating pattern GI.

The organic film patterns PP may be disposed in contact with at least one side of the semiconductor pattern APP. For example, as shown in the exemplary embodiment of FIG. 18, a first organic film pattern of the organic film patterns PP may be in direct contact with a first lateral edge of the first semiconductor region AP1, and a second organic film pattern of the organic film patterns PP may be in contact with an opposite second lateral edge of the third semiconductor region AP3.

The organic film patterns PP may be disposed in contact with at least one side of the ohmic pattern OP. For example, as shown in the exemplary embodiment of FIG. 18, a first organic film pattern of the organic film patterns PP may be in direct contact with a first lateral edge of the ohmic contact layer OC disposed on the first semiconductor region AP1, and the second organic film pattern of the organic film patterns PP may be in direct contact with an opposite second lateral edge of the ohmic contact layer OC disposed on the third semiconductor region AP3.

As described above, the organic film patterns PP may be in contact with one side (e.g., a lateral edge) of each first metal part of the first metal layer M1 comprising the gate insulating pattern GI, the semiconductor pattern APP, and the ohmic pattern OP. The organic film patterns PP may be disposed in contact with one side of the second metal layer M2. The second metal layer M2 may be disposed on the ohmic pattern OP, and a first portion of the second metal layer M2 may be located at the same level as the first metal layer M1. The first metal layer M1 and the second metal layer M2 positioned at the same level may be electrically insulated from each other by the organic film patterns PP.

The organic film patterns PP may be disposed between the first metal layer M1 and the first portion of the second metal layer M2, a first side of the organic film patterns PP may be in contact with the first metal layer M1, the gate insulating pattern GI, the semiconductor pattern APP and the ohmic pattern OP, and the opposite second side of the organic film patterns PP may be in contact with the second metal layer M2. The second metal layer M2 may include second metal parts including the first to third source electrodes SE1, SE2 and SE3, the first to third drain electrodes DE1, DE2 and DE3, and the reference line RL, as described above.

For example, the first drain electrode DE1 may extend (e.g., in a thickness direction of the first substrate SUB1) from the ohmic contact layers OC to the first substrate SUB1. One of the organic film patterns PP may be disposed continuously between the first drain electrode DE1 and the ohmic contact layers OC, between the first drain electrode DE1 and the first semiconductor region AP1 of the semiconductor pattern, between the first drain electrode DE1 and the gate insulating pattern G1, and between the first drain electrode DE1 and the first gate electrode GE1. The third source electrode SE3 may be extended from the ohmic contact layer OC to the first substrate SUB1 between the ohmic contact layer OC and adjacent ohmic contact layer OC. A second organic film pattern of the organic film patterns PP may be disposed continuously between the third source electrode SE3 and the ohmic contact layer OC, between the third source electrode SE1 and the third semiconductor region AP3 of the semiconductor pattern APP, between the third source electrode SE3 and the gate insulating pattern GI, and between the third source electrode SE3 and the third gate electrode GE3. In addition, the reference line RL may extend (e.g., in a thickness direction of the first substrate SUB1) from the ohmic pattern OP to the first substrate SUB1. A third organic film pattern of the organic film patterns PP may be disposed continuously between the ohmic pattern OP and the reference line RL, between the semiconductor pattern APP and the reference line RL, between the gate insulating pattern GI and the reference line RL, and between the storage line 127 and the reference line RL.

The above-described organic film patterns of FIG. 18 may be disposed between the first metal layer and the second metal layer. The organic film patterns PP according to this exemplary embodiment may be disposed between the second metal layer and the gate insulating pattern on the first metal layer, between the second metal layer and the semiconductor pattern and between the second metal layer and the ohmic pattern, in addition to between the second metal layer and the first metal layer. Therefore, according to this exemplary embodiment, the organic film patterns may prevent the characteristics of the elements from deteriorating by insulating the side surfaces of the semiconductor pattern and the ohmic pattern and protecting them during subsequent processes.

Hereinafter, a method of fabricating the display device shown in the exemplary embodiment of FIG. 18 will be described.

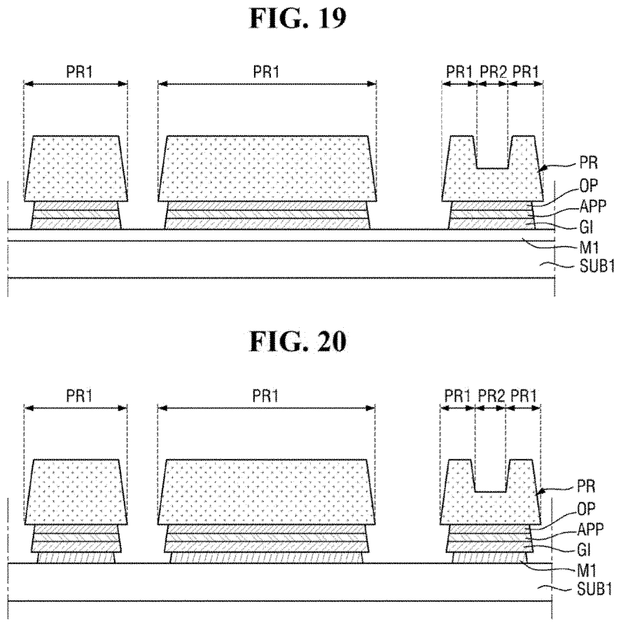

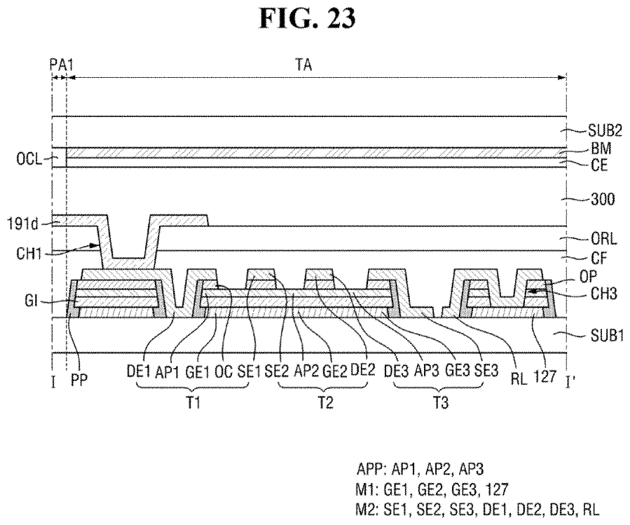

FIGS. 19 to 23 are cross-sectional views showing steps of a method of fabricating a display device according to another exemplary embodiment of the present inventive concepts. Some of the steps according to this exemplary embodiment are identical to the processing steps described above with respect to exemplary embodiments of FIGS. 6 and 7; and, therefore, the redundant description will be omitted for convenience of explanation.

Referring to the exemplary embodiment of FIG. 19, dry etching is performed on regions other than the first photoresist region PRI and the second photoresist region PR2, to remove the gate insulating material layer 115, the first semiconductor material layer 120, and the second semiconductor material layer 130. Accordingly, the gate insulating pattern GI, the semiconductor pattern APP and the ohmic pattern OP may be formed under the first photoresist region PR1 and the second photoresist region PR2. In doing so, unlike the above-described exemplary embodiment, the gate insulating pattern GI, the semiconductor pattern APP and the ohmic pattern OP are over-etched during the dry etching process. In an exemplary embodiment, the overetching may be performed by increasing dry etching process conditions, such as increasing the power or time. Therefore, according to this exemplary embodiment of the present inventive concepts, the gate insulating pattern GI, the semiconductor pattern APP, and the ohmic pattern OP are over-etched, thereby increasing the undercuts underneath the photoresist pattern PR.

Referring to the exemplary embodiment of FIG. 20, the first metal material layer 110 is wet etched using the photoresist pattern PR as a mask, to form first metal layers M1. In an exemplary embodiment, the first metal layer M1 may be over-etched during the wet etching process so that it is formed in an undercut shape underneath the gate insulating pattern GI.

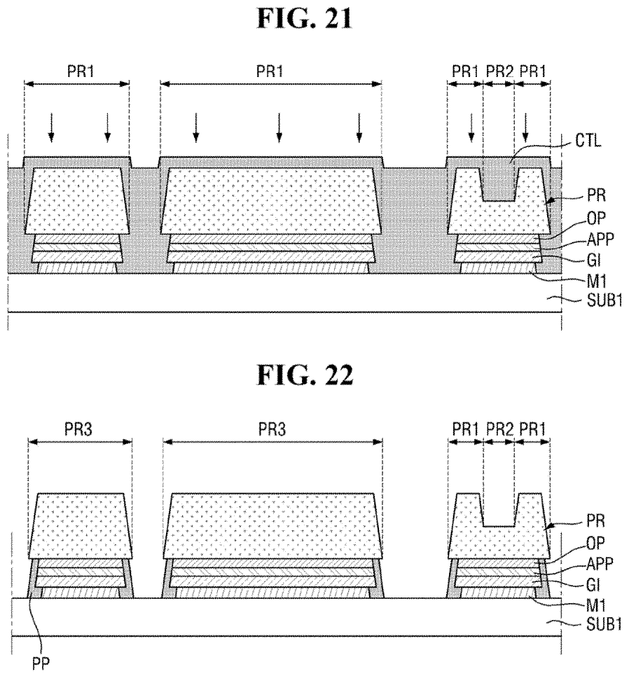

Referring to the exemplary embodiment of FIG. 21, an organic coating layer CTL is coated over the photoresist pattern PR formed on the first substrate SUB1. The organic coating layer CTL may be formed of a photosensitive organic material or a non-photosensitive organic material. For example, when the organic coating layer CTL is formed of a photosensitive organic material, UV exposure is carried out on the entire surface of the first substrate SUB1.

Referring to the exemplary embodiment of FIG. 22, an organic coating layer CTL exposed to UV is developed to form organic film patterns PP. For example, the organic coating layer CTL is exposed to UV using the photoresist pattern PR as a mask. The organic coating layer CTL in the undercuts underneath the photoresist pattern PR is not exposed to UV. Accordingly, when the UV-exposed organic coating layer CTL is developed, the organic film patterns PP are formed on both sides of the first metal layer M1, the gate insulating pattern GI, the semiconductor pattern APP and the ohmic pattern OP. For example, the organic film patterns PP may directly contact lateral edges of the first metal layer M1, the gate insulating pattern GI, the semiconductor pattern APP and the ohmic pattern OP

On the other hand, when the organic coating layer CTL is formed of a non-photosensitive organic material, by dry etching without UV exposure in the exemplary embodiment of FIG. 21, the organic film patterns PP having the same shape as in the exemplary embodiment of FIG. 22 may be formed.

The subsequent processes are identical to those described above with respect to the exemplary embodiments of FIGS. 12 to 15; and, therefore, the redundant description will be omitted for convenience of explanation.

As described above, in the display device according to an exemplary embodiment of the present inventive concepts, the organic film patterns are formed between the second metal layer and each of the first metal layer, the gate insulating pattern, the semiconductor pattern and the ohmic pattern, so that the side surfaces (e.g., lateral edges) of the semiconductor pattern and the ohmic pattern are insulated and protected during subsequent processes, thereby preventing the characteristics of the elements from deteriorating.

In concluding the detailed description, those skilled in the art will appreciate that many variations and modifications can be made to the exemplary embodiments without substantially departing from the principles of the present inventive concepts. Therefore, the disclosed exemplary embodiments of the present inventive concepts are used in a generic and descriptive sense only and not for purposes of limitation

What is claimed is:

1. A display device comprising:
a substrate;
a first metal layer disposed on the substrate, the first metal layer including first metal parts;
organic film patterns disposed on the substrate and positioned adjacent to lateral edges of the first metal parts of the first metal layer;
a gate insulating pattern disposed on the first metal parts of the first metal layer and the organic film patterns; and
a semiconductor pattern disposed on the gate insulating pattern,
wherein lateral side surfaces of the gate insulating pattern protrude outward from the lateral edges of each first metal part of the first metal layer that the gate insulating pattern is disposed thereon and the gate insulating pattern at least partially overlaps each organic film pattern that the gate insulating pattern is disposed thereon.

2. The display device of claim 1, wherein the organic film patterns directly contact lateral edges of the first metal parts of the first metal layer.

3. The display device of claim 2, wherein lateral edges of each of the organic film patterns are aligned with or protrude from lateral edges of the gate insulating pattern disposed thereon.

4. The display device of claim 2, wherein:
a first metal part of the first metal layer comprises a first side surface located on a first side and a second side surface located on an opposite second side;
a first organic film pattern of the organic film patterns directly contacts the first side surface of the first metal part; and
a second organic film pattern of the organic film patterns directly contacts the second side surface of the first metal part.

5. The display device of claim 1, wherein each of the organic film patterns directly contact one side of the first metal layer and directly contact a lower surface of the gate insulating pattern.

6. The display device of claim 1, further comprising:
a second metal layer disposed on the semiconductor pattern, a first portion of the second metal layer is positioned at a same level as the first metal layer, wherein the organic film patterns are positioned adjacent to side surfaces of the first portion of the second metal layer to electrically insulate the second metal layer from the first metal layer.

7. The display device of claim 6, wherein:
the semiconductor pattern and the gate insulating pattern comprises a contact hole exposing the first metal layer; and
the second metal layer is connected to the first metal layer through the contact hole.

8. The display device of claim 6, wherein the first metal parts of the first metal layer comprises a gate electrode and a storage line, and wherein the second metal layer includes second metal parts comprising a source electrode, a drain electrode, and a voltage-dividing reference line.

9. A display device comprising:
a substrate;
a first metal layer disposed on the substrate, the first metal layer including first metal parts;
organic film patterns disposed on the substrate and positioned adjacent to lateral edges of the first metal parts of the first metal layer;
a gate insulating pattern disposed on the first metal parts of the first metal layer and the organic film patterns; and
a semiconductor pattern disposed on the gate insulating pattern,
wherein lateral side surfaces of the gate insulating pattern protrude outward from the lateral edges of each first metal part of the first metal layer that the gate insulating pattern is disposed thereon, and
wherein the organic film patterns directly contact lateral edges of the gate insulating pattern.

10. The display device of claim 9, wherein the organic film patterns directly contact lateral edges of the semiconductor pattern.

11. The display device of claim 10, wherein outer lateral side surfaces of the organic film patterns protrude from the lateral edges of the gate insulating pattern.

12. The display device of claim 9, wherein:
a first metal part of the first metal layer comprises a first side surface located on a first side and a second side surface located on an opposite second side;
a first organic film pattern of the organic film patterns directly contacts the first side surface of the first metal part;
a second organic film of the organic film patterns directly contacts the second side surface of the first metal part.

13. The display device of claim 9, wherein each of the organic film patterns directly contacts one side of the first metal layer and directly contacts a lower surface of the gate insulating pattern.

14. The display device of claim 9, further comprising:
a second metal layer disposed on the semiconductor pattern, a first portion of the second metal layer is positioned at a same level as the first metal layer, wherein the organic film patterns are positioned adjacent to side surfaces of the first portion of the second metal layer to electrically insulate the second metal layer from the first metal layer.

15. The display device of claim 14, wherein the second metal layer is disposed on outer sides of the organic film patterns and directly contacts the organic film patterns.

16. The display device of claim 14, wherein:
the organic film patterns are disposed between the first metal layer and the second metal layer;
a first side of the organic film patterns directly contact side surfaces of the first metal layer and an opposite second side of the organic film patterns directly contact side surfaces of the second metal layer.

17. A method of fabricating a display device, the method comprising:
stacking a first metal material layer, a gate insulating material layer and a semiconductor material layer on a substrate;
forming a first metal layer, a gate insulating pattern and a semiconductor pattern by etching the first metal material layer, the gate insulating material layer and the semiconductor material layer;
forming organic film patterns positioned adjacent to lateral edges of the first metal layer by coating an organic material on the substrate; and
forming a second metal layer by stacking and patterning a second metal material layer on the semiconductor pattern.

18. The method of claim 17, wherein the forming of the first metal layer, the gate insulating pattern and the semiconductor pattern comprises:
forming a photoresist pattern on the semiconductor material layer;
forming the first metal layer by wet etching the first metal material layer;
forming the gate insulating pattern and the semiconductor pattern by dry etching the gate insulating material layer and the semiconductor material layer; and
removing the photoresist pattern.

19. The method of claim 18, wherein:
the organic material is a photosensitive organic material; and
the organic film patterns are formed by exposing and developing the photosensitive organic material using the gate insulating pattern as a mask.

20. The method of claim 19, wherein:
the organic material is a non-photosensitive organic material; and
the organic film patterns are formed by dry etching the non-photosensitive organic material using the photoresist pattern as a mask.
